(19) United States
(12) Patent Application Publication
(10) Pub. No.: US 2025/0203894 A1
(43) Pub. Date: Jun. 19, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yuto ADACHI, Ibo Hyogo (JP); Makoto MIZUKAMI, Ibo Hyogo (JP); Yoichi HORI, Himeji Hyogo (JP)

(21) Appl. No.: 19/067,776

(22) Filed: Feb. 28, 2025

Related U.S. Application Data
(63) Continuation of application No. PCT/JP2024/005342, filed on Feb. 15, 2024.

(30) Foreign Application Priority Data
Jul. 13, 2023 (JP) 2023-115490

(51) Int. Cl. H10D 8/60; H10D 8/00; H10D 62/10; H10D 62/60; H10D 62/832; H10D 62/834; H10D 64/64

(52) U.S. Cl. CPC H10D 8/60; H10D 8/411; H10D 62/108; H10D 62/124; H10D 62/60; H10D 62/8325; H10D 62/834; H10D 64/64

(57) ABSTRACT

According to one embodiment, a semiconductor device includes a first electrode, a first conductive member, a first semiconductor region, and a second semiconductor region. The first semiconductor region is of a first conductivity type and is provided between the first electrode and the first conductive member. The first semiconductor region includes first to third partial regions. The first semiconductor region and the first conductive member forms a Schottky junction, The second semiconductor region is of a second conductivity type. The second semiconductor region includes a plurality of first portions extending along a first direction, a plurality of second portions extending along a second direction, and a third portion.

### CROSS-REFERENCE TO RELATED APPLICATIONS

This is a continuation application of International Application PCT/JP2024/005342, filed on Feb. 15, 2024. This application also claims priority to Japanese Patent Application No. 2023-115490, filed on Jul. 13, 2023. The entire contents of which are incorporated herein by reference.

### FIELD

Embodiments described herein relate generally to a semiconductor device.

### BACKGROUND

For example, it is desired to improve the characteristics of semiconductor devices such as junction barrier Schottky diodes (JBS).

### BRIEF DESCRIPTION OF THE DRAWINGS

FIGS. 1A to 1C are schematic views illustrating a semiconductor device according to a first embodiment;

FIG. 2A to FIG. 2C are schematic views illustrating a semiconductor device according to a first embodiment;

FIG. 3A and FIG. 3B are schematic views illustrating a semiconductor device according to a first embodiment;

FIGS. 4A to 4C are schematic cross-sectional views illustrating a semiconductor device according to a second embodiment; and

FIGS. 5A to 5C are schematic cross-sectional views illustrating a semiconductor device according to a second embodiment.

### DETAILED DESCRIPTION

According to one embodiment, a semiconductor device includes a first electrode, a first conductive member, a first semiconductor region, and a second semiconductor region. The first semiconductor region is of a first conductivity type and is provided between the first electrode and the first conductive member. The first semiconductor region includes a first partial region, a second partial region, and a third partial region. The first semiconductor region and the first conductive member forms a Schottky junction, The second semiconductor region is of a second conductivity type. The second semiconductor region includes a plurality of first portions extending along a first direction, a plurality of second portions extending along a second direction, and a third portion. The first direction crosses a third direction from the first electrode to the first conductive member. The second direction crosses a first plane including the first direction and the third direction. The third portion is provided around the plurality of second portions in a second plane including the first direction and the second direction. The third portion is continuous with the plurality of second portions. The first partial region is provided between the first electrode and the plurality of first portions and between the first electrode and the second partial region in the third direction. The second partial region is provided between one of the plurality of first portions and another one of the plurality of first portions in the second direction. The third partial region is provided between the plurality of first portions and the first conductive member and between the second partial region and the first conductive member in the third direction. The third partial region is provided between one of the plurality of second portions and another one of the plurality of second portions in the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

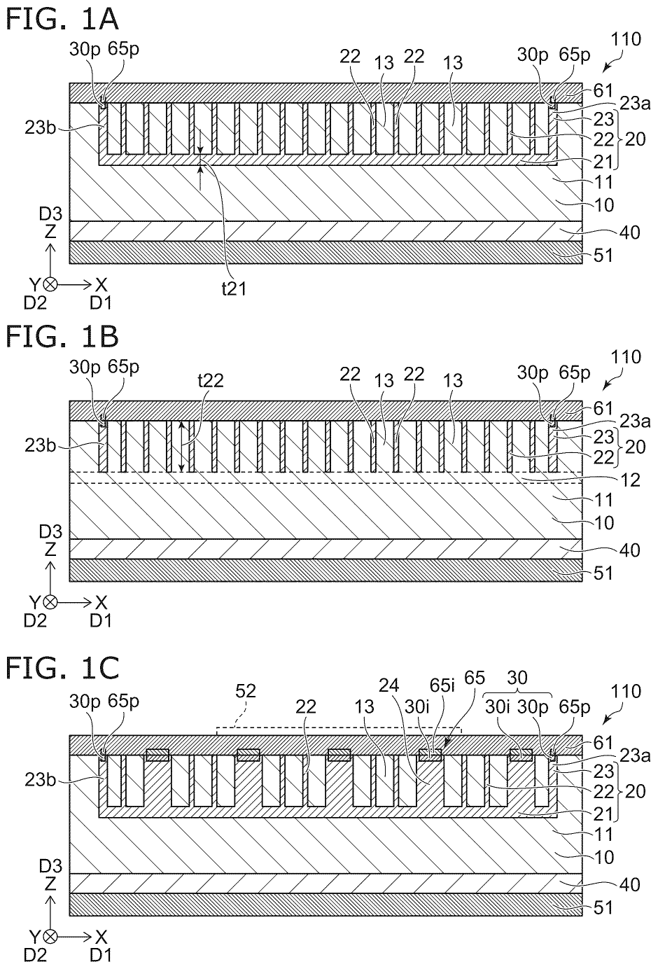

FIGS. 1A to 1C, FIG. 2A to FIG. 2C, FIG. 3A, and FIG. 3B are schematic views illustrating a semiconductor device according to a first embodiment.

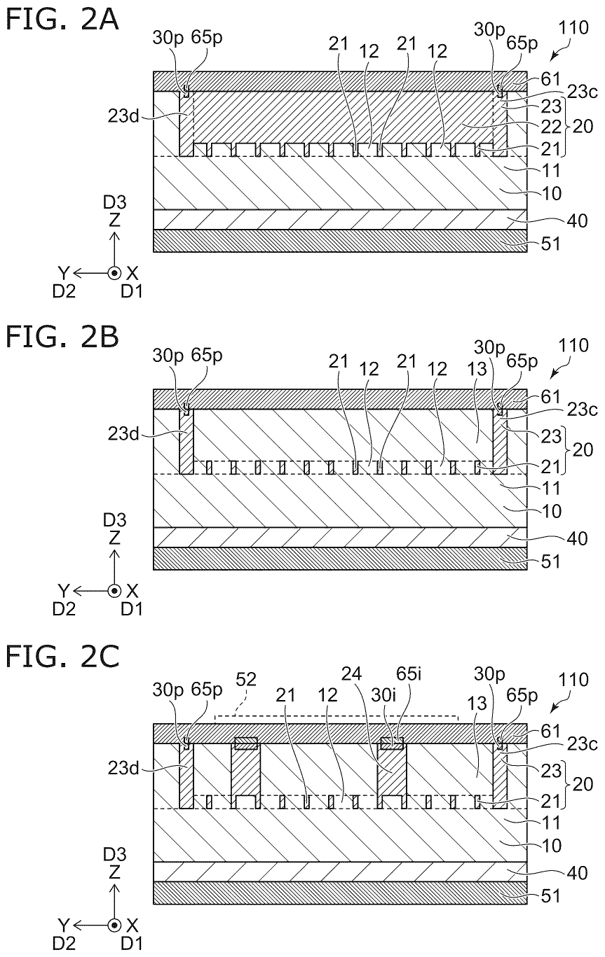

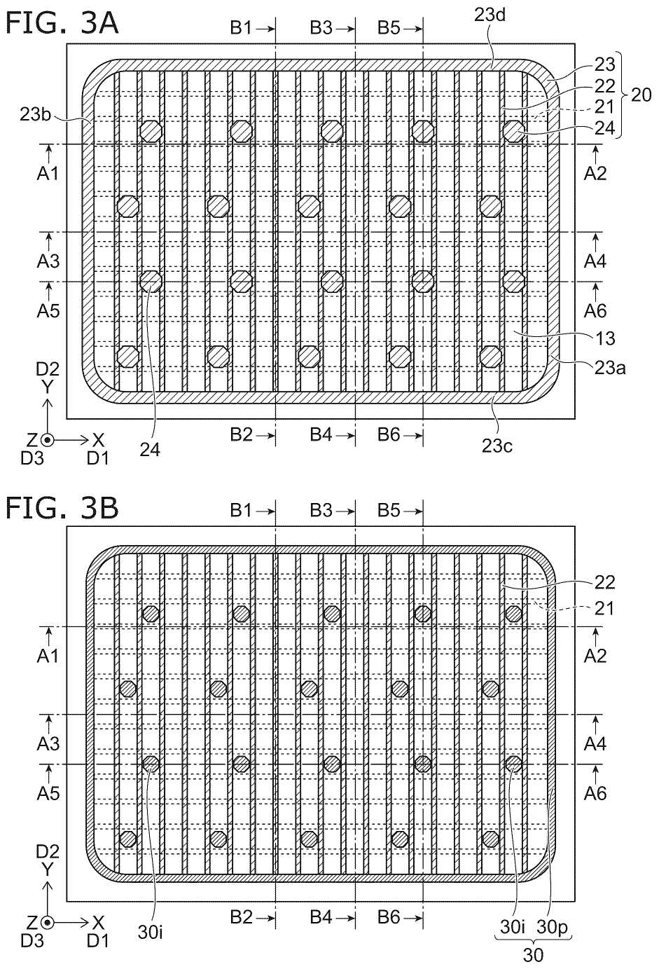

FIGS. 1A to 1C are cross-sectional views taken along lines A1-A2, A3-A4, and A5-A6 in FIGS. 3A and 3B. FIGS. 2A to 2C are cross-sectional views taken along lines B1-B2, B3-B4, and B5-B6 in FIGS. 3A and 3B.

As shown in FIGS. 1A to 1C and FIGS. 2A to 2C, a semiconductor device 110 according to the embodiment includes a first electrode 51, a first conductive member 61, a first semiconductor region 10, and a second semiconductor region 20.

The first semiconductor region 10 is provided between the first electrode 51 and the first conductive member 61. The first semiconductor region 10 is of a first conductivity type. The first semiconductor region 10 includes a first partial region 11, a second partial region 12, and a third partial region 13. The first semiconductor region 10 and the first conductive member 61 form a Schottky junction.

The second semiconductor region 20 is of a second conductivity type. The first conductivity type is one of n-type and p-type. The second conductivity type is the other of n-type and p-type. In the following, the first conductivity type is n-type, and the second conductivity type is p-type.

As shown in FIG. 3A, the second semiconductor region 20 includes a plurality of first portions 21, a plurality of second portions 22, and a third portion 23. The plurality of first portions 21 extend along a first direction D1. The plurality of second portions 22 extend along a second direction D2. The first direction D1 crosses a third direction D3 from the first electrode 51 to the first conductive member 61. The second direction D2 crosses a first plane including the first direction D1 and the third direction D3.

The first direction D1 is, for example, an X-axis direction. A direction perpendicular to the X-axis direction is defined as a Y-axis direction. A direction perpendicular to the X-axis direction and the Y-axis direction is defined as a Z-axis direction. The third direction D3 is, for example, the Z-axis direction. In one example, the second direction D2 may be the Y-axis direction. The second direction D2 may be inclined with respect to the first direction D1. The first plane corresponds to, for example, the X-Z plane.

For example, the plurality of first portions 21 are arranged along the second direction D2. The plurality of second portions 22 are arranged along the first direction D1. For example, the plurality of second portions 22 contact the plurality of first portions 21. The boundaries between the plurality of second portions 22 and the plurality of first portions 21 may be clear or unclear.

FIG. 3A is a cross-sectional view on the X-Y plane including the plurality of second portions 22. As shown in FIG. 3A, the third portion 23 is provided around the plurality of second portions 22 in a second plane including the first direction D1 and the second direction D2. The second plane corresponds to, for example, the X-Y plane. The third portion 23 is continuous with the plurality of second portions 22. For example, the third portion 23 surrounds the plurality of second portions 22 in the second plane (X-Y plane). The third portion 23 has, for example, an outer peripheral annular pin structure.

The inside of the region surrounded by the third portion 23 is, for example, a cell region. The outside of the third portion 23 is, for example, a peripheral region.

The third portion 23 may be provided around the plurality of first portions 21 on the second plane. The third portion 23 may be continuous with the plurality of first portions 21.

As shown in FIGS. 1A and 1B, the first partial region 11 is provided between the first electrode 51 and the plurality of first portions 21 and between the first electrode 51 and the second partial region 12 in the third direction D3. The first partial region 11 is provided between the first electrode 51 and the second partial region 12 in the third direction D3.

As shown in FIGS. 2A and 2B, the second partial region 12 is provided between one of the plurality of first portions 21 and another one of the plurality of first portions 21 in the second direction D2. The third partial region 13 is provided between the plurality of first portions 21 and the first conductive member 61 and between the second partial region 12 and the first conductive member 61 in the third direction D3.

As shown in FIGS. 1A and 1B, the third partial region 13 is provided between one of the plurality of second portions 22 and another one of the plurality of second portions 22 in the first direction D1.

As shown in FIG. 1C and FIG. 2C, the semiconductor device 110 may further include a second electrode 52. The second electrode 52 is electrically connected to the first conductive member 61. In the example, the first conductive member 61 is provided between at least a part of the second semiconductor region 20 and at least a part of the second electrode 52.

In the semiconductor device 110, the characteristics of the current flowing between the first electrode 51 and the second electrode 52 change according to the polarity of the relative potential in the first electrode 51 and the second electrode 52. The semiconductor device 110 is, for example, a diode. The state in which the potential of the second electrode 52 is higher than the potential of the first electrode 51 is a forward state. A state in which the potential of the second electrode 52 is lower than the potential of the first electrode 51 is a reverse bias state.

In the semiconductor device 110, the first semiconductor region 10 and the first conductive member 61 form a Schottky junction. Further, in the semiconductor device 110, the second semiconductor region 20 of the second conductivity type is provided. The semiconductor device 110 is, for example, a JBS. The first partial region 11 corresponds to, for example, an n-type drift layer.

In JBSs, there is a first reference example in which a plurality of p-type regions extending along one direction are provided. In the first reference example, when a reverse bias voltage is applied, a depletion layer is formed in a region including a p-type region and an n-type drift layer. By covering the Schottky junction with the depletion layer, leakage current can be reduced, for example. In the first reference example, when the area or density of the p region is increased to suppress leakage current, the area of the Schottky junction is reduced. As a result, the forward voltage increases and its superiority as a Schottky barrier diode is lost.

The semiconductor device 110 is provided with the plurality of first portions 21 extending along the first direction D1 and the plurality of second portions 22 extending along the second direction D2. The plurality of first portions 21 are provided at positions apart from the first conductive member 61. The third partial region 13 of the first conductivity type (n-type) exists between the plurality of first portions 21 and the first conductive member 61. In the semiconductor device 110, for example, the plurality of first portions 21 and the plurality of second portions 22 effectively form a depletion layer over a wide area when a reverse bias voltage is applied. This suppresses leakage current. In the semiconductor device 110, the third partial region 13 forms a Schottky junction with the first conductive member 61. Thereby, the area of the Schottky junction is maintained wide. This provides a sufficiently low forward voltage.

In the embodiment, the third portion 23 is provided around the plurality of second portions 22 in the second plane (X-Y plane). The third portion 23 is continuous with the plurality of second portions 22. By providing such a third portion 23 makes it easy to improve surge resistance. According to the embodiment, in addition to a small leakage current and a low forward current, a large surge resistance can be obtained. According to the embodiment, a semiconductor device with improved characteristics can be provided.

For example, a second reference example may be considered in which the third portion 23 (outer peripheral annular pin structure) is not provided. In the embodiment, the outer peripheral annular pin structure can improve surge resistance compared to the second reference example.

As shown in FIGS. 1C and 2C, the semiconductor device 110 may further include a third semiconductor region 30. The third semiconductor region 30 is of the second conductivity type. The impurity concentration of the second conductivity type in the third semiconductor region 30 is higher than the impurity concentration of the second conductivity type in the second semiconductor region 20. The third semiconductor region 30 is, for example, a p⁺-region. The second semiconductor region 20 is, for example, a p-region.

The third semiconductor region 30 includes a peripheral region 30p. The peripheral region 30p is provided between the third portion 23 and the first conductive member 61 in the third direction D3. In this example, semiconductor device 110 further includes a compound member 65. The compound member 65 includes a peripheral member 65p. The peripheral member 65p is provided between the peripheral region 30p and the first conductive member 61 in the third direction D3. The first conductive member 61 includes a first metal element. The compound member 65 includes a first metal element and silicon. The first metal element is, for example, Ni. In this case, the compound member 65 includes Ni silicide.

Good ohmic contact can be obtained by such peripheral region 30p and peripheral member 65p. Thereby, for example, when applying a reverse bias to the diode, holes in the second semiconductor region 20 can be efficiently discharged to the first conductive member 61 (Schottky electrode). For example, a depletion layer is generated at high speed around the second semiconductor region 20. As a result, recovery characteristics can be improved. For example, reverse recovery time can be shortened. For example, reverse recovery current can be reduced.

As shown in FIGS. 1C and 2C, the second semiconductor region 20 may further include a fourth portion 24. At least a part of the fourth portion 24 is provided between one of the plurality of second portions 22 and another one of the plurality of second portions 22 in the first direction D1. The third semiconductor region 30 further includes an inner region 30i. The inner region 30i is provided between the fourth portion 24 and the first conductive member 61 in the third direction D3. The compound member 65 further includes an inner member 65i. The inner member 65i is provided between the inner region 30i and the first conductive member 61 in the third direction D3.

The breakdown voltage of the chip can be improved by the first semiconductor region 10, the second semiconductor region 20, and the third semiconductor region 30. For example, in the pin structure (the dot portion and the outermost periphery), the breakdown voltage is lower than the breakdown voltage at the Schottky interface (the interface between the first conductive member and the third partial region). For example, when a reverse bias surge is applied, the pin structure breaks down first, and current flows through the pin structure first. Thereby, it is possible to suppress destruction caused by application of a high electric field to the Schottky interface.

FIG. 3B illustrates a cross section in the X-Y plane including the third semiconductor region 30. On the other hand, as already explained, FIG. 3A illustrates a cross section in the X-Y plane including the plurality of second portions 22. As shown in FIG. 3A, for example, the third portion 23 may include a first extending portion 23a, a second extending portion 23b, a third extending portion 23c, and a fourth extending portion 23d. The first extending portion 23a extends along the second direction D2. The second extending portion 23b extends along the second direction D2. The third extending portion 23c extends along the first direction D1. The fourth extending portion 23d extends along the first direction D1. A direction from the second extending portion 23b to the first extending portion 23a is along the first direction D1. A direction from the third extending portion 23c to the fourth extending portion 23d is along the second direction D2. These multiple extending portions may be continuous with each other.

As shown in FIG. 1A, a thickness of one of the plurality of first portions 21 in the third direction D3 is defined as a first thickness t21. As shown in FIG. 1B, a thickness of one of the plurality of second portions 22 in the third direction D3 is defined as a second thickness t22. In one example, the first thickness t21 may be not less than 0.5 μm and not more than 1.5 μm. The second thickness t22 may be, for example, not less than 0.5 μm and not more than 1.5 μm.

In the embodiment, for example, the first semiconductor region 10 and the second semiconductor region 20 include SiC. The first semiconductor region 10 and the second semiconductor region 20 may include at least one selected from the group consisting of 4H-SiC, 6H-SiC, and 3C-SiC. These semiconductor regions include crystals.

For example, the first semiconductor region 10 includes at least one element selected from the group consisting of N, P, and As (a first element that is an impurity of the first conductivity type). For example, the second semiconductor region 20 includes at least one element selected from the group consisting of B, A1, and Ga (a second element that is an impurity of the second conductivity type).

As shown in FIGS. 1A to 1C and FIGS. 2A to 2C, the semiconductor device 110 may further include a fourth semiconductor region 40. The fourth semiconductor region 40 is of the first conductivity type. The fourth semiconductor region 40 is provided between the first electrode 51 and the first semiconductor region 10. The impurity concentration of the first conductivity type in the fourth semiconductor region 40 is higher than the impurity concentration of the first conductivity type in the first semiconductor region 10. Low electrical resistance can be obtained between the first electrode 51 and the first semiconductor region 10.

In one example, the concentration of the first element (n-type) in the first semiconductor region 10 is, for example, not less than 1.0×10¹⁵ cm⁻³ and not more than 1.0×10¹⁷ cm⁻³. In one example, the concentration of the second element (p-type) in the second semiconductor region 20 is, for example, not less than 1.0×10¹² cm⁻³ and not more than 1.0×10¹⁴ cm⁻³. In one example, the concentration of the second element (p-type) in the third semiconductor region 30 is, for example, not less than 1.0×10¹² cm⁻³ and not more than 1.0×10¹⁴ cm⁻³. In one example, the concentration of the first element (n-type) in the fourth semiconductor region 40 is, for example, not less than 0.5×10¹⁸ cm⁻³ and not more than 0.5×10¹⁹ cm⁻³.

The first conductive member 61 includes at least one element (for example, a first metal element) selected from the group consisting of Pt, V, and Ti. A stable Schottky junction can be obtained.

The first electrode 51 includes, for example, at least one selected from the group consisting of Ti, Ni, and Au. The second electrode 52 includes, for example, Al.

In the semiconductor device 110 described above, the third portion 23 overlaps the plurality of first portions 21 in the X-Y plane. The plurality of first portions 21 are continuous with the third portion 23.

### Second Embodiment

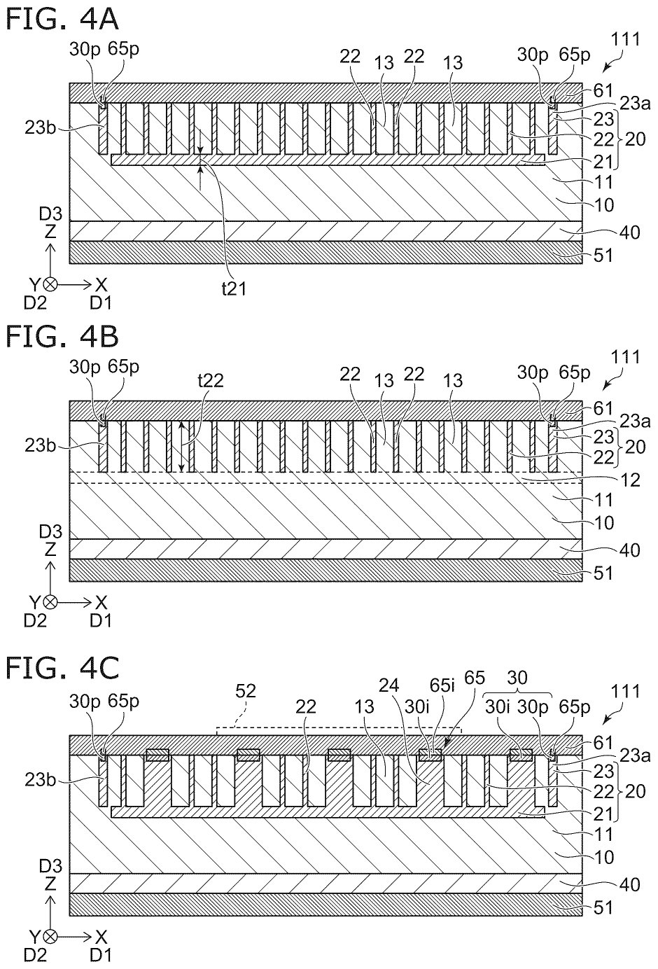

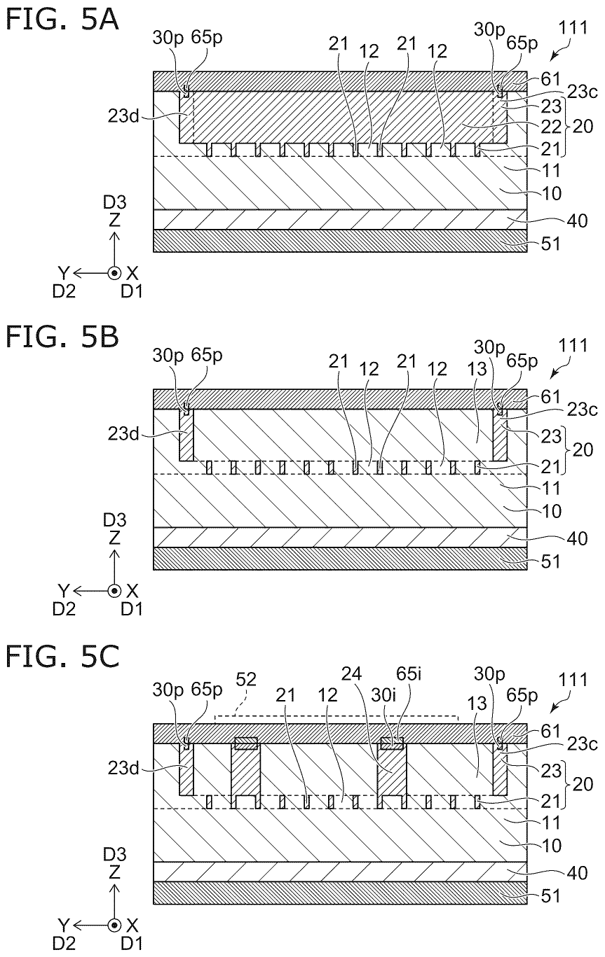

FIGS. 4A to 4C and FIGS. 5A to 5C are schematic cross-sectional views illustrating a semiconductor device according to a second embodiment.

FIGS. 4A to 4C are cross-sectional views corresponding to the A1-A2 line, the A3-A4 line, and the A5-A6 line in FIGS. 3A and 3B. FIGS. 5A to 5C are cross-sectional views corresponding to the B1-B2 line, the B3-B4 line, and the B5-B6 line in FIGS. 3A and 3B.

Like the semiconductor device 111, at least a part of the third portion 23 does not have to overlap the plurality of first portions 21 in the X-Y plane. Even in such a semiconductor device 111, a small leakage current and a low forward voltage can be obtained. According to the embodiment, a semiconductor device with improved characteristics can be provided.

In the embodiments, information regarding length and thickness is obtained by electron microscopy or the like. Information regarding the composition of the material can be obtained by SIMS (Secondary Ion Mass Spectrometry), EDX (Energy dispersive X-ray spectroscopy), or the like.

The embodiments may include the following Technical proposals:

### (Technical Proposal 1)

A semiconductor device, comprising:
a first electrode;
a first conductive member;
a first semiconductor region of a first conductivity type provided between the first electrode and the first conductive member, the first semiconductor region including a first partial region, a second partial region, and a third partial region, the first semiconductor region and the first conductive member forming a Schottky junction;
a second semiconductor region of a second conductivity type, the second semiconductor region including a plurality of first portions extending along a first direction, a plurality of second portions extending along a second direction, and a third portion, the first direction crossing a third direction from the first electrode to the first conductive member, the second direction crossing a first plane including the first direction and the third direction, the third portion being provided around the plurality of second portions in a second plane including the first direction and the second direction, the third portion being continuous with the plurality of second portions, the first partial region being provided between the first electrode and the plurality of first portions and between the first electrode and the second partial region in the third direction, the second partial region being provided between one of the plurality of first portions and another one of the plurality of first portions in the second direction, the third partial region being provided between the plurality of first portions and the first conductive member and between the second partial region and the first conductive member in the third direction, the third partial region being provided between one of the plurality of second portions and another one of the plurality of second portions in the first direction.

### (Technical Proposal 2)

The semiconductor device according to Technical proposal 1, wherein
the third portion is continuous with the plurality of first portions.

### (Technical Proposal 3)

The semiconductor device according to Technical proposal 1 or 2, wherein
the third portion surrounds the plurality of second portions in the second plane.

### (Technical Proposal 4)

The semiconductor device according to any one of Technical proposals 1-3, wherein
the third portion including:
   a first extending portion extending along the second direction,
   a second extending portion extending along the second direction,
   a third extending portion extending along the first direction, and
   a fourth extending portion extending along the first direction,
a direction from the second extending portion to the first extending portion is along the first direction, and
a direction from the third extending portion to the fourth extending portion is along the second direction.

### (Technical Proposal 5)

The semiconductor device according to any one of Technical proposals 1-4, further comprising:
a third semiconductor region of the second conductivity type,
the third semiconductor region including a peripheral region,
the peripheral region being provided between the third portion and the first conductive member in the third direction,
an impurity concentration of the second conductivity type in the third semiconductor region being higher than an impurity concentration of the second conductivity type in the second semiconductor region.

### (Technical Proposal 6)

The semiconductor device according to Technical proposal 5, further comprising:

a compound member,
the compound member including a peripheral member,
the peripheral member being provided between the peripheral region and the first conductive member in the third direction,
the first conductive member including a first metal element, and
the compound member includes the first metal element and silicon.

### (Technical Proposal 7)

The semiconductor device according to Technical proposal 6, wherein
the second semiconductor region further includes a fourth portion,
at least a part of the fourth portion is provided between the one of the plurality of second portions and the other one of the plurality of second portions in the first direction,
the third semiconductor region further includes an inner region,
the inner region is provided between the fourth portion and the first conductive member in the third direction,
the compound member further includes an inner member,
the inner member is provided between the inner region and the first conductive member in the third direction.

### (Technical Proposal 8)

The semiconductor device according to any one of Technical proposals 1-7, wherein
the first conductive member includes at least one selected from the group consisting of Pt, V, and Ti.

### (Technical Proposal 9)

The semiconductor device according to any one of Technical proposals 1-8, wherein
the plurality of second portions are in contact with the plurality of first portions.

### (Technical Proposal 10)

The semiconductor device according to any one of Technical proposals 1-9, wherein
a first thickness of the one of the plurality of first portions in the third direction is not less than 0.5 μm and not more than 1.5 μm.

### (Technical Proposal 11)

The semiconductor device according to Technical proposal 10, wherein
a second thickness of the one of the plurality of second portions in the third direction is not less than 0.5 μm and not more than 1.5 μm.

### (Technical Proposal 12)

The semiconductor device according to any one of Technical proposal 1-11, wherein
the first semiconductor region and the second semiconductor region include SiC.

### (Technical Proposal 13)

The semiconductor device according to any one of Technical proposal 1-11, wherein
the first semiconductor region and the second semiconductor region include at least one selected from the group consisting of 4H-SiC, 6H-SiC, and 3C-SiC.

### (Technical Proposal 14)

The semiconductor device according to any one of Technical proposal 1-13, wherein
the first semiconductor region includes at least one selected from the group consisting of N, P, and As, and
the second semiconductor region includes at least one selected from the group consisting of B, A1, and Ga.

### (Technical Proposal 15)

The semiconductor device according to any one of Technical proposal 1-14, wherein
the first partial region is provided between the first electrode and the second partial region in the third direction.

### (Technical Proposal 16)

The semiconductor device according to any one of Technical proposal 1-15, wherein
the plurality of first portions are arranged along the second direction, and
the plurality of second portions are arranged along the first direction.

### (Technical Proposal 17)

The semiconductor device according to any one of Technical proposal 1-16, further comprising:
a second electrode electrically connected to the first conductive member.

### (Technical Proposal 18)

The semiconductor device according to Technical proposal 17, wherein
the second electrode includes A1.

### (Technical Proposal 19)

The semiconductor device according to Technical proposal 17 or 18, wherein
the first conductive member is provided between at least a part of the second semiconductor region and at least a part of the second electrode.

### (Technical Proposal 20)

The semiconductor device according to any one of Technical proposals 1-19, further comprising:
a fourth semiconductor region of the first conductivity type,
the fourth semiconductor region being provided between the first electrode and the first semiconductor region,
an impurity concentration of the first conductivity type in the fourth semiconductor region being higher than an impurity concentration of the first conductivity type in the first semiconductor region.

According to the embodiment, a semiconductor device with improved characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as semiconductor region, conductive members, electrodes, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a first conductive member;
a first semiconductor region of a first conductivity type provided between the first electrode and the first conductive member, the first semiconductor region including a first partial region, a second partial region, and a third partial region, the first semiconductor region and the first conductive member forming a Schottky junction;
a second semiconductor region of a second conductivity type, the second semiconductor region including a plurality of first portions extending along a first direction, a plurality of second portions extending along a second direction, and a third portion, the first direction crossing a third direction from the first electrode to the first conductive member, the second direction crossing a first plane including the first direction and the third direction, the third portion being provided around the plurality of second portions in a second plane including the first direction and the second direction, the third portion being continuous with the plurality of second portions, the first partial region being provided between the first electrode and the plurality of first portions and between the first electrode and the second partial region in the third direction, the second partial region being provided between one of the plurality of first portions and another one of the plurality of first portions in the second direction, the third partial region being provided between the plurality of first portions and the first conductive member and between the second partial region and the first conductive member in the third direction, the third partial region being provided between one of the plurality of second portions and another one of the plurality of second portions in the first direction.

2. The semiconductor device according to claim 1, wherein the third portion is continuous with the plurality of first portions.

3. The semiconductor device according to claim 1, wherein
the third portion surrounds the plurality of second portions in the second plane.

4. The semiconductor device according to claim 1, wherein
the third portion including:
a first extending portion extending along the second direction,
a second extending portion extending along the second direction,
a third extending portion extending along the first direction, and
a fourth extending portion extending along the first direction,
a direction from the second extending portion to the first extending portion is along the first direction, and
a direction from the third extending portion to the fourth extending portion is along the second direction.

5. The semiconductor device according to claim 1, further comprising:
a third semiconductor region of the second conductivity type,
the third semiconductor region including a peripheral region,
the peripheral region being provided between the third portion and the first conductive member in the third direction,
an impurity concentration of the second conductivity type in the third semiconductor region being higher than an impurity concentration of the second conductivity type in the second semiconductor region.

6. The semiconductor device according to claim 5, further comprising:
a compound member,
the compound member including a peripheral member,
the peripheral member being provided between the peripheral region and the first conductive member in the third direction,
the first conductive member including a first metal element, and
the compound member includes the first metal element and silicon.

7. The semiconductor device according to claim 6, wherein
the second semiconductor region further includes a fourth portion,
at least a part of the fourth portion is provided between the one of the plurality of second portions and the other one of the plurality of second portions in the first direction,
the third semiconductor region further includes an inner region,
the inner region is provided between the fourth portion and the first conductive member in the third direction,
the compound member further includes an inner member,
the inner member is provided between the inner region and the first conductive member in the third direction.

8. The semiconductor device according to claim 1, wherein
the first conductive member includes at least one selected from the group consisting of Pt, V, and Ti.

9. The semiconductor device according to claim 1, wherein
the plurality of second portions are in contact with the plurality of first portions.

10. The semiconductor device according to claim 1, wherein
a first thickness of the one of the plurality of first portions in the third direction is not less than 0.5 μm and not more than 1.5 μm.

11. The semiconductor device according to claim 10, wherein
a second thickness of the one of the plurality of second portions in the third direction is not less than 0.5 μm and not more than 1.5 μm.

12. The semiconductor device according to claim 1, wherein
the first semiconductor region and the second semiconductor region include SiC.

13. The semiconductor device according to claim 1, wherein
the first semiconductor region and the second semiconductor region include at least one selected from the group consisting of 4H-SiC, 6H-SiC, and 3C-SiC.

14. The semiconductor device according to claim 1, wherein
the first semiconductor region includes at least one selected from the group consisting of N, P, and As, and
the second semiconductor region includes at least one selected from the group consisting of B, Al, and Ga.

15. The semiconductor device according to claim 1, wherein
the first partial region is provided between the first electrode and the second partial region in the third direction.

16. The semiconductor device according to claim 1, wherein
the plurality of first portions are arranged along the second direction, and
the plurality of second portions are arranged along the first direction.

17. The semiconductor device according to claim 1, further comprising:
a second electrode electrically connected to the first conductive member.

18. The semiconductor device according to claim 17, wherein
the second electrode includes A1.

19. The semiconductor device according to claim 17, wherein
the first conductive member is provided between at least a part of the second semiconductor region and at least a part of the second electrode.

20. The semiconductor device according to claim 1, further comprising:
a fourth semiconductor region of the first conductivity type,
the fourth semiconductor region being provided between the first electrode and the first semiconductor region,
an impurity concentration of the first conductivity type in the fourth semiconductor region being higher than an impurity concentration of the first conductivity type in the first semiconductor region.
